(19) United States
(12) Patent Application Publication
(10) Pub. No.: US 2024/0283434 A1
(43) Pub. Date: Aug. 22, 2024

(54) LIGHT DETECTOR AND RANGE FINDER

(71) Applicant: Sharp Semiconductor Innovation Corporation, Tenri City (JP)

(72) Inventors: Hideki SATO, Tenri City (JP); Takahiro INOUE, Tenri City (JP); Takayuki SHIMIZU, Tenri City (JP); Tetsuro IKEDA, Tenri City (JP); AHMAD SHAHIR BIN AHMAD NOR, Tenri City (JP)

(21) Appl. No.: 18/443,969

(22) Filed: Feb. 16, 2024

(30) Foreign Application Priority Data
Feb. 16, 2023 (JP) 2023-022198

(51) Int. Cl. H03K 3/033; G01S 7/484; G01S 7/4863

(52) U.S. Cl. CPC H03K 3/033; G01S 7/484; G01S 7/4863

(57) ABSTRACT

A light detector includes a SPAD; a resistor component; a switch element; and a control circuit configured to control the switch element to discharge or charge a first node. In response to a change in a potential of the first node from a first potential to a second potential, the control circuit turns on the switch element until a second period elapses after a lapse of a first period measured from the change to the second potential, or until the potential of the first node changes back to the first potential during the second period, and the control circuit turns off the switch element upon a lapse of the second period without the potential of the first node changing back to the first potential, and the control circuit turns on the switch element again after a lapse of a third period measured from the turning off of the switch element.

### CROSS-REFERENCE TO RELATED APPLICATION

The present application claims priority from Japanese Application JP2023-022198, the content of which is hereby incorporated by reference into this application.

### BACKGROUND OF THE INVENTION

### 1. Field of the Invention

The present disclosure relates to a light detector and a range finder.

### 2. Description of the Related Art

Time-of-flight (ToF) sensors have been recently used as range finders. Such a range finder enables a distance to a detection target to be calculated based on a time measured until light emitted from a light-emitting unit reflects on the detection target and is then detected by a light-receiving unit.

Single-photon avalanche diodes (SPADs) have been recently used as elements that detect light in the forgoing light-receiving unit. International Publication No. 2019/087783 discloses a method for preventing prolongation of a dead time resulting from an afterpulse, in which electrons are trapped at a high level during the SPAD's avalanche breakdown, to thus cause an avalanche breakdown after a time lag.

### SUMMARY OF THE INVENTION

A light-receiving unit including an SPAD needs to discharge a node charged, for instance, by an avalanche breakdown after the avalanche breakdown ends, and to apply a high reverse voltage across the SPAD, to be thus ready for the next light incidence; hence, a time period until the discharge is completed constitutes a dead time. This discharge completion period can be shortened by using a low-resistance switch in the discharge, but if an avalanche breakdown occurs again during the discharge due to, for instance, ambient light or noise, a state of equilibrium is established between a current resulting from the avalanche breakdown and a current flowing through the switch, thereby fixing the node's voltage, thus further extending the dead time in some cases.

Moreover, the method described in International Publication No. 2019/087783 does not solve this problem.

One aspect of the present disclosure has been made in view of the foregoing problem and aims to provide a light detector and a range finder both of which can prevent prolongation of a dead time that results from an avalanche breakdown.

A light detector according to one aspect of the present disclosure includes the following: a single-photon avalanche diode (SPAD) having one end connected to a first node; a resistor component having one end connected to the first node; a switch element having one end connected to the first node; and a control circuit configured to control the switch element to discharge or charge the first node, wherein in response to a change in a potential of the first node from a first potential to a second potential, the control circuit turns on the switch element until a second period elapses after a lapse of a first period measured from the change to the second potential, or until the potential of the first node changes back to the first potential during the second period, the control circuit turns off the switch element upon a lapse of the second period without the potential of the first node changing back to the first potential, and the control circuit turns on the switch element again after a lapse of a third period measured from the turning off of the switch element.

A range finder according to one aspect of the present disclosure includes the following: a light-emitting element configured to emit pulsed light to a detection target at predetermined time intervals; a light detector configured to receive reflected light that is the pulsed light emitted from the light-emitting element, and that is reflected on the detection target; and a distance operation circuit configured to perform an operation of a distance to the detection target in accordance with a timing at which the pulsed light is emitted by the light-emitting element, and a timing at which the reflected light is received by the light detector, wherein the light detector includes the following: a single-photon avalanche diode (SPAD) having one end connected to a first node, and configured to receive the reflected light; a resistor component having one end connected to the first node; a switch element having one end connected to the first node; and a control circuit configured to control the switch element to discharge or charge the first node, and wherein in response to a change in a potential of the first node from a first potential to a second potential, the control circuit turns on the switch element until a second period elapses after a lapse of a first period measured from the change to the second potential, or until the potential of the first node changes back to the first potential during the second period, the control circuit turns off the switch element upon a lapse of the second period without the potential of the first node changing back to the first potential, and the control circuit turns on the switch element again after a lapse of a third period measured from the turning off of the switch element.

### BRIEF DESCRIPTION OF THE DRAWINGS

FIG. 1 is a sectional view of a configuration of a range finder according to a preferred embodiment;

FIG. 2 is a functional block diagram of the range finder according to the preferred embodiment;

FIG. 3 is a circuit diagram of a light detector according to the preferred embodiment;

FIG. 4 is a circuit diagram of a delay circuit according to the preferred embodiment;

FIG. 5 is a timing chart of each node during the operation of the light detector according to the preferred embodiment;

FIG. 6 is a timing chart of each node during the operation of the light detector according to the preferred embodiment;

FIG. 7 is a sectional view of a configuration of the range finder according to a first modification of the preferred embodiment;

FIG. 8 is a functional block diagram of the range finder according to the first modification of the preferred embodiment; and

FIG. 9 is a circuit diagram of the light detector according to a second modification of the preferred embodiment.

### DETAILED DESCRIPTION OF THE INVENTION

A preferred embodiment of the present invention will be described with reference to the drawings. It is noted that identical or equivalent components will be denoted by the same signs throughout the drawings, and that the description of redundancies will be omitted.

A light detector and a range finder according to a preferred embodiment of the present invention will be described. The following describes, by way of example, a ToF sensor as the range finder. Further, this preferred embodiment will mainly describe a light detector including SPADs that receives reflected light from a detection target with a ToF sensor, and including a control circuit that controls the SPAD's operation.

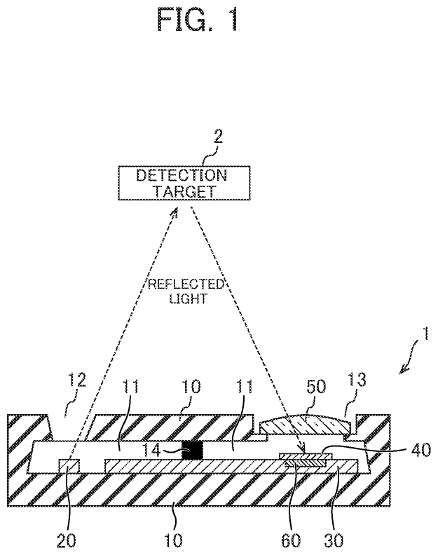

FIG. 1 is a schematic sectional view of a configuration of a range finder 1 according to this preferred embodiment. As illustrated in FIG. 1, the range finder 1 includes a case 10, a light-emitting element 20, a light-reception integrated circuit (IC) 30, an optical filter 40, and a condenser lens 50.

The case 10 contains the light-emitting element 20, the light-reception IC 30, and the optical filter 40 and protects them from external impact, dirt, and other things. The case 10 has the following inside: a hollow 11 for mounting the light-emitting element 20, light-reception IC 30, and optical filter 40; an opening 12 for radiating light to a detection target 2; and an opening 13 for receiving reflected light from the detection target 2.

The light-emitting element 20 is incorporated inside the case 10. The light-emitting element 20 is a vertical-cavity surface-emitting laser (VCSEL) for instance. The light-emitting element 20 is thus disposed in such a manner that the opening 12 is positioned above the light-emitting element 20. The light-emitting element 20 also emits pulsed light to the detection target 2 at, for instance, predetermined time intervals.

The light-reception IC 30 is incorporated inside the case 10, like the light-emitting element 20. The light-reception IC incorporates the light detector 60. The light detector 60 includes a plurality of SPADs, which receive light that is the pulsed light emitted from the light-emitting element 20, and that is reflected on the detection target 2. The light detector 60 is thus provided within the light-reception IC 30 so as to be positioned directly under the opening 13. The configuration and operation of the light detector 60 will be detailed later on. It is noted that inside the hollow 11 of the case 10 is a light-blocking wall 14 provided between the light-emitting element 20 and light detector 60 so as to separate them from each other. By virtue of the light-blocking wall 14, the pulsed light output by the light-emitting element 20 can be prevented from being received by the light detector 60 via the space within the hollow 11.

The optical filter 40 is provided on the light-reception IC 30 and covers the upper surface of the light detector 60. To be more specific, the optical filter 40 is provided so as to cover a surface through which the SPADs receive the reflected light. The optical filter 40 enables the light detector 60 to detect, for instance, only reflected light having a particular wavelength band. As a matter of course, the optical filter 40 may not be provided in some cases, or the optical filter 40 may function as a protective filter that protects the SPADs in other cases.

The condenser lens 50 is provided over the opening 13. Moreover, the condenser lens 50 condenses the reflected light from the detection target 2 and causes the reflected light to enter the light detector 60.

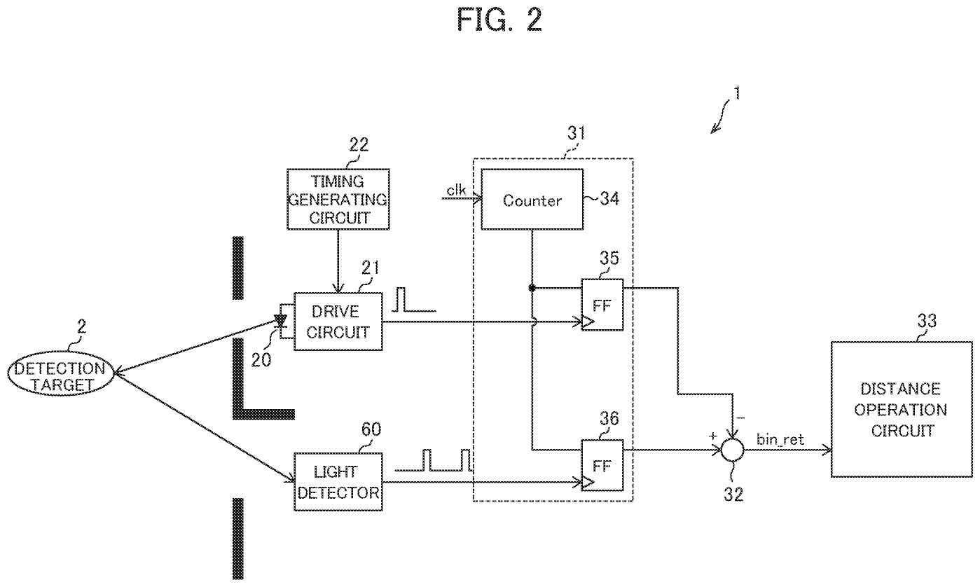

In the foregoing configuration, a distance to the detection target 2 can be determined by determining how long it takes for the light output from the light-emitting element 20 to be reflected on the detection target 2 and then detected by the light detector 60. Next, a functional block configuration of the range finder 1 for performing such an operation will be described with reference to FIG. 2. FIG. 2 is a block diagram of the range finder 1.

As illustrated in FIG. 2, the range finder 1 includes the light detector 60, the light-emitting element 20, a drive circuit 21, a timing generator circuit 22, time to-digital convertor (TDC) 31, an addition-and-subtraction circuit 32, and a distance operation circuit 33.

The timing generator circuit 22 generates a pulse signal at predetermined intervals on the basis of a clock signal, which is input from outside for instance, and outputs the pulse signal to the drive circuit 21.

The drive circuit 21 drives the light-emitting element 20 to cause the light-emitting element 20 to emit the foregoing pulsed light. To be more specific, the drive circuit 21 causes the light-emitting element 20 to emit light on the basis of the timing of the pulse signal received from the timing generator circuit 22. The drive circuit 21 also generates a pulse signal at a timing synchronized with the timing of driving the light-emitting element 20 and outputs the pulse signal to the TDC 31.

The light detector 60 receives the reflected light from the detection target 2 by using the SPADs, as earlier described. The light detector 60 then generates a pulse signal at a timing synchronized with the timing of receiving the reflected light and outputs the pulse signal to the TDC 31.

The TDC 31 coverts the timing of the pulse signal received from the drive circuit 21 (i.e., the timing at which the light-emitting element 20 emits light) to a digital value converts the timing of the pulse signal received from the light detector 60 (i.e., the timing at which the SPADs receive light) to a digital value. The TDC 31 includes a counter circuit 34, and two flip-flops 35 and 36.

The counter circuit 34 receives a clock signal having a constant frequency from outside. The counter circuit 34 then outputs a digital value with reference to this clock signal. For instance, the counter circuit 34 outputs digital values of “0x0” to “0xF” in hexadecimal. The digital value returns to “0x0” upon reaching “0xF”.

The flip-flop 35 is a D-F/F for instance, and the flip-flop 35 receives the digital value output by the counter circuit 34, and the pulse signal output by the drive circuit 21, retains the digital value at the timing of receiving the pulse signal and outputs the digital value to the addition-and-subtraction circuit 32. The flip-flop 36 is also a D-F/F for instance, and the flip-flop 36 receives the digital value output by the counter circuit 34, and the pulse signal output by the light detector 60, and the flip-flop 36 retains the digital value at the timing of receiving the pulse signal and outputs the digital value to the addition-and-subtraction circuit 32.

The addition-and-subtraction circuit 32 calculates a difference bin_ret between the digital values output from the flip-flops 35 and 36 and outputs the difference bin_ret to the distance operation circuit 33.

The distance operation circuit 33 performs an operation of the distance to the detection target 2 on the basis of the relationship between the difference bin_ret received from the addition-and-subtraction circuit 32 and the number of times of the reception of this difference. A conventionally known method can be used for this method.

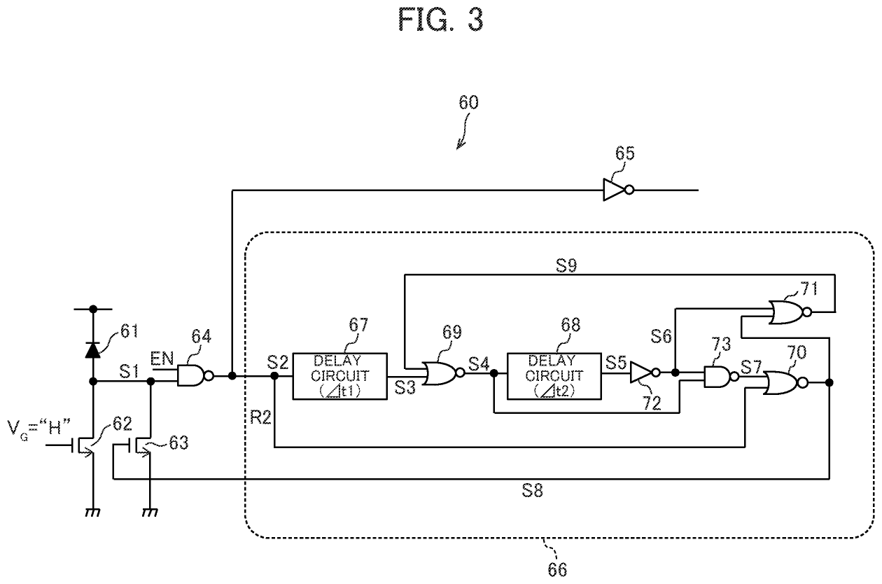

Next, the light detector 60 will be detailed. FIG. 3 is a circuit diagram of the light detector 60 according to this preferred embodiment. As illustrated in FIG. 3, the light detector 60 includes an SPAD 61, n-channel MOS transistors 62 and 63, a NAND gate 64, an inverter 65, and a control circuit 66.

The SPAD 61 has one end (an anode in this example) connected to a first node S1 (hereinafter, merely referred to as a nod S1), and the other end connected to a high-voltage node. The potential of the high-voltage node is the sum of a breakdown voltage V_{BD} of the SPAD 61 and an overvoltage V_{EX} of the same, and the overvoltage V_{EX} is set at a voltage equal to or larger than an input-determination voltage at the node S1 of the NAND gate 64. Moreover, the SPAD 61 receives, for instance, the reflected light from the detection target 2 during application of the voltage V_{BD} plus V_{EX} between its anode and cathode, to generate an avalanche breakdown (avalanche multiplication), thus passing a current from the cathode to the anode.

The n-channel MOS transistor 62 has one end (a drain in this example) connected to the node S1, the other end (a source in this example) connected to a low-voltage node (a ground potential in this example), and a gate to which a voltage V_{G} is applied. When the range finder 1 operates, the voltage V_{G} is set at a logic “H” level, thus turning on the MOS transistor 62. As such, the MOS transistor 62 substantially functions as a resistor component.

The n-channel MOS transistor 63 has one end (a drain in this example) connected to the node S1, the other end (a source in this example) connected to a low-voltage node (a ground potential in this example), and a gate to which a signal S8, which is provided from the control circuit 66, is input. Moreover, the MOS transistor 63 is turned on when a node S8 is at a logic “H” level. As such, the MOS transistor 63 substantially functions as a switch. It is noted that the resistance value between the source and drain in at least the linear region and saturated region of the MOS transistor 63 is smaller than the resistance value between the source and drain of the MOS transistor 62.

The NAND gate 64 performs a negative AND operation between a signal at the node S1 and a signal EN and outputs the operation result to a node S2. When the range finder 1 operates, the signal EN is set at a logic “H” level. Thus, the NAND gate 64 outputs a logic “L” level when the node S1 is at a logic “H” level, and the NAND gate 64 outputs a logic “H” level when the node S1 is at a logic “L” level.

The inverter 65 inverts the logic level of the node S2 and outputs the inverted result to the flip-flop 35 of the TDC 31, described with reference to FIG. 2.

The control circuit 66 controls the MOS transistor 63 in accordance with the logic level of the node S2, to discharge the node S1. To be more specific, in response to a rise in the potential of the node S1 from a first potential (in this example, 0 volts) to a second potential (in this example, a voltage V1, which is a potential corresponding to a logic “H” level), the control circuit 66 turns on the MOS transistor 63 until a second period Δt2 elapses after a lapse of a first period Δt1 measured from the change to the second potential, or until the potential of the node S1 changes back to the first potential during the second period Δt2, the control circuit 66 turns off the MOS transistor 63 upon a lapse of the second period Δt2 without the potential of the node S1 changing back to the first potential, and the control circuit 66 turns on the MOS transistor 63 again after a lapse of a third period measured from the turning off of the MOS transistor 63.

In more detail, the control circuit 66 includes delay circuits 67 and 68, NOR gates 69, 70, and 71, an inverter 72, and a NAND gate 73. The delay circuit (first delay circuit) 67 delays a signal of the node S2 by the first period Δt1 and outputs the delayed signal to a node S3. The NOR gate 69 performs a negative OR operation between the signal of the node S3 and a signal of a node S9, to which an output signal of the NOR gate 71 is provided, and outputs the operation result to a node S4. The delay circuit (second delay circuit) 68 delays the signal of the node S4 by the second period Δt2 and outputs the delayed signal to a node S5. The inverter 72 inverts the logic level of the node S5 and outputs the inverted result to a node S6. The NAND gate 73 performs a negative AND operation between the signal of the node S4 and the signal of the node S6 and outputs the operation result to a node S7. The NOR gate 70 performs a negative OR operation between the signal of the node S2 and the signal of the node S7 and outputs the operation result to the node S8. That is, the MOS transistor 63 is controlled based on the operation result generated by the NOR gate 70. The NOR gate 71 performs a negative OR operation between the signal of the node S6 and the signal of the node S8 and outputs the operation result to the node S9.

In the foregoing configuration, the NOR gate 69 functions as a determination circuit that determines whether to discharge the node S1, in accordance with an output of the delay circuit 67 and an output of the NOR gate 71.

Further, the delay circuit 68, inverter 72, and NAND gate 73 function as a first pulse control circuit that generates, in accordance with an output of the determination circuit, a pulse signal that enables the MOS transistor 63 to be turned on during the second period Δt2. To be more specific, the inverter 72 and NAND gate 73 function as a pulse generating circuit that generates, for the node S7, a pulse signal enabled during the second period Δt2 in accordance with an input signal to the delay circuit 68 and an output signal of the delay circuit 68.

The NOR gate 70 functions as a second pulse control circuit that disables a pulse signal in response to a drop in the potential of the node S1 from the second potential to the first potential. To be more specific, the second pulse control circuit receives the pulse signal output from the first pulse control circuit to the node S7, and in accordance with a signal based on the potential of the node S1 (i.e., the signal of the node S2), the second pulse control circuit disables the pulse signal. To be more specific, the second pulse control circuit disables the pulse signal from the first pulse control circuit and sets the node S8 at an “L” level, because once the node S1 is discharged sufficiently, there is no need to turn on the MOS transistor 63 any longer on or after this time point.

The NOR gate 71 functions as a third pulse control circuit that causes the foregoing determination circuit to determine again the discharge of the node S1, upon a lapse of the second period Δt2 without the potential of the node S1 reaching the first potential. To be more specific, the third pulse control circuit generates a signal for a determination to discharge the first node in accordance with a signal based on the delay circuit 68 (i.e., the signal of the node S6) and an output signal of the second pulse control circuit (i.e., the signal of the node S8), and the third pulse control circuit outputs the generated signal to the node S9.

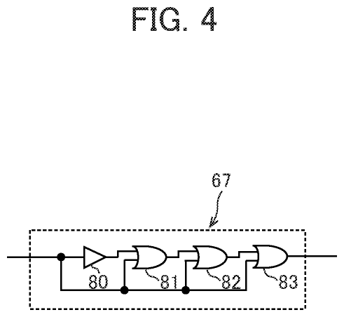

FIG. 4 is a circuit diagram of the delay circuit 67. As illustrated, the delay circuit 67 includes a buffer 80, and OR gates 81, 82 and 83. The buffer 80 waveform-shapes the signal of the node S2. The OR gate 81 performs an OR operation between the signal of the node S2 and an output signal of the buffer 80. The OR gate 82 performs an OR operation between the signal of the node S2 and an output signal of the OR gate 81. The OR gate 83 performs an OR operation between the signal of the node S2 and an output signal of the OR gate 82. Then, the operation result in the OR gate 83 is output to the node S3.

In the delay circuit 67 with the foregoing configuration, the transition speed of the logic level of an output signal is different between a transition of an input signal from a first logic level (“H” or “L”) to a second logic level (“L” or “H”) different from the first logic level, and a transition of the input signal from the second logic level (“L” or “H”) to the first logic level (“H” or “L”). In the case of this example, an output of the NOR gate 83 changes promptly to a logic “H” level upon transition of the input signal from a logic “L” level to a logic “H” level. Conversely, upon transition of the input signal from the logic “H” level to the logic “L” level, the output of the NOR gate 83 changes from the logic “H” level to the logic “L” level at the time when the input signal at the logic “L” level passes through the buffer 80 and NOR gates 81 and 82 and then has reached the NOR gate 83. In this way, in the configuration in FIG. 4, a transition from the logic “H” level to the logic “L” level occurs slowly, and a transition from the logic “L” level to the logic “H” level occurs quickly.

It is noted that unlike the delay circuit 67, the delay circuit 68 delays an input signal by the period Δt2 when the input signal changes in either case: from a logic “H” level to a logic “L” level, or from the logic “L” level to the logic “H” level.

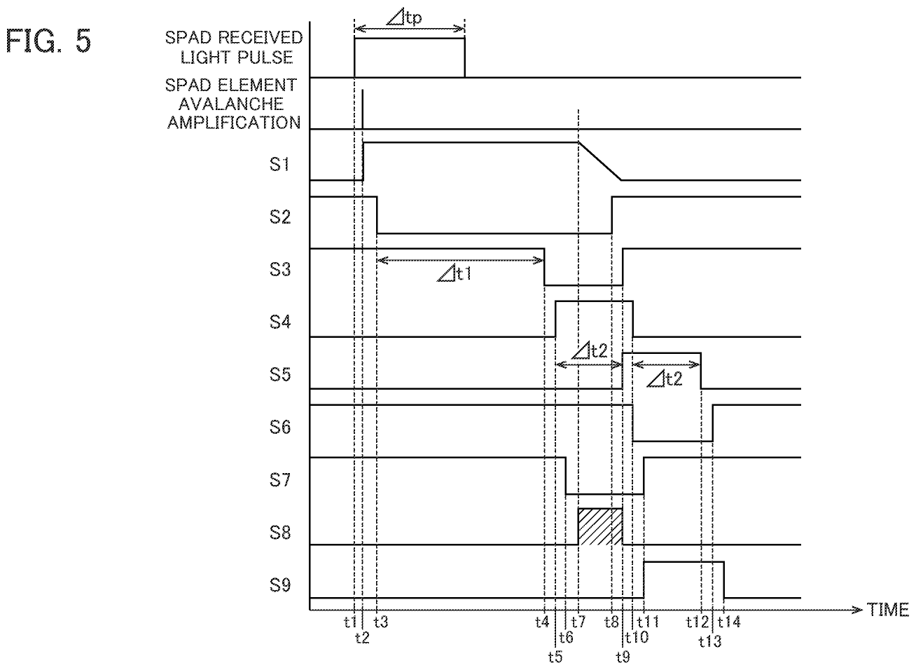

Next, the operation of the light detector 60 will be described with reference to a timing chart in FIG. 5. FIG. 5 is a timing chart of a received light pulse of the SPAD 61 (i.e., light received from the detection target 2), of the state of an avalanche amplification in the SPAD 61 (the longitudinal line in the drawing indicates an avalanche breakdown), and of signals of the nodes S1 to S9, and FIG. 5 illustrates a case where an avalanche breakdown does not occur during the discharge of the node S1.

As illustrated, the SPAD 61 receives reflected light from the detection target 2 as a received light pulse at time t1, and thus, an avalanche amplification occurs in the SPAD 61 at time t2. Accordingly, a current flows from the SPAD 61 toward the MOS transistor 62, and at the almost same time as time t2, the potential of the node S1 rises to a voltage V_{EX} in consequence of a voltage drop in the MOS transistor 62. This potential rise in the node S1 reduces the potential difference between the anode and cathode of the SPAD 61 to V_{BD}, stopping the avalanche amplification immediately. Further, the potential of the node S1 rises to stand at a logic “H” level, and accordingly, an output of the NAND gate 64, that is, the node S2 changes to a logic “L” level at time t3.

A signal of the node S2 is input to the control circuit 66 and is delayed by a period Δt1 by the delay circuit 67, and the node S3 changes to the logic “L” level at time t4. In consequence of this transition of the node S3 to the “L” level, an operation result in the NOR gate 69, that is, the node S4 changes to the logic “H” level at time t5. A signal of the node S4 is input to the delay circuit 68 and is also input to the NAND gate 73 without passing through the delay circuit 68 and inverter 72. Consequently, an operation result in the NAND gate 73, that is, the node S7 changes to the logic “L” level at time t6. In consequence of this transition of the node S7 to the logic “L” level, an operation result in the NOR gate 70, that is, the node S8 is set at the logic “H” level at time t7. This turns on the MOS transistor 63 to thus discharge the node S1, and the potential of the node S1 thus lowers rapidly.

Then, upon the node S1 lowering to the threshold of the logic “L” level at time t8, the node S2 changes to the logic “H” level. In consequence of this transition of the node S2 to the logic “H” level, an operation result in the NOR gate 70, that is, the node S8 changes to the logic “L” level at time t9. This turns off the MOS transistor 63. At this time point, the node S1 stands at about 0 volts, and the potential difference between the anode and cathode of the SPAD 61 returns to V_{BD} plus V_{EX}, thereby bringing the SPAD 61 into condition to be able to generate an avalanche breakdown again by receiving light.

Furthermore, in consequence of the transition of the node S2 to the logic “L” level, the node S3 changes to the logic “H” level at time t9. As earlier described, the delay circuit 67 little delays a signal when an input signal changes from an “L” level to a “H” level. In consequence of the transition of the node S3 to the logic “H” level, an operation result in the NOR gate 69 stands at the logic “L” level at time t0, and the node S4 changes to the logic “L” level at time t10 as well.

Further, the delay circuit 68 changes the node S5 to the logic “H” level at time t9, which is delayed by the period Δt2 from time t5, at which the node S4 changes to the logic “H” level, and the inverter 72 sets the node S6 at the logic “L” level at time t10. Consequently, an operation result in the NOR gate 71, that is, the node S9 changes to the logic “H” level at time t11. Thereafter, at time t12, the node S5 changes to the logic “L” level after a period Δt2 delay from the node S4, and accordingly, the node S9 changes to the logic “L” level at time t14.

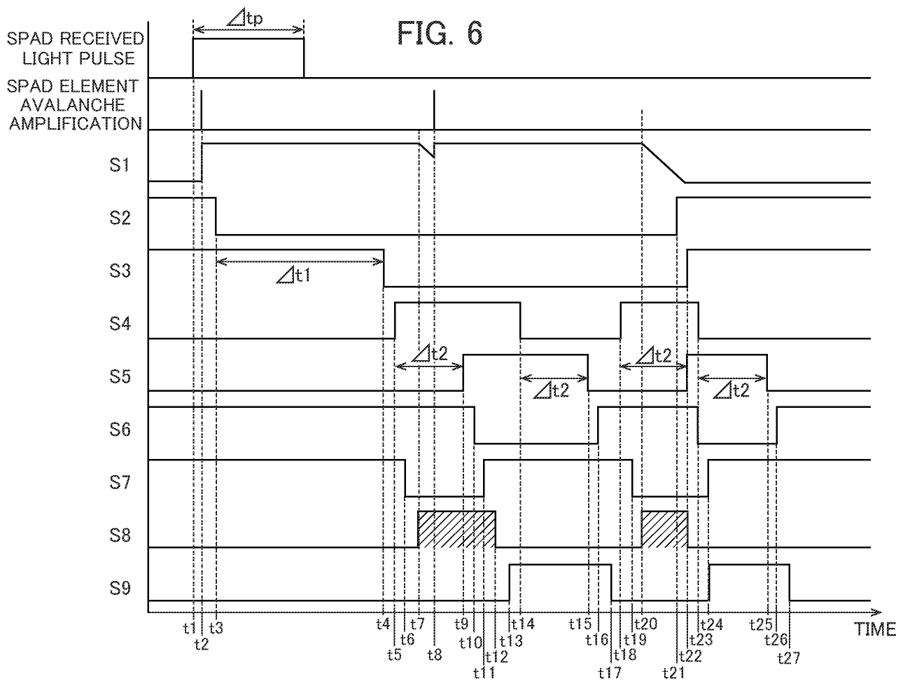

Next, an instance where an avalanche breakdown occurs in the SPAD 61 while the MOS transistor 63 discharges the node S1 during the operation of the light detector 60 described with reference to FIG. 5 will be described with reference to a timing chart in FIG. 6. Like FIG. 5, FIG. 6 is a timing chart of a received light pulse of the SPAD 61, of the state of an avalanche amplification in the SPAD 61, and of signals of the nodes S1 to S9.

As illustrated, operations at times t1 to t7 are those described with reference to FIG. 5. The node S8 changes to a logic “H” level at time t7, thus, as earlier described, turning on the MOS transistor 63, thus lowering the potential of the node S1 rapidly. However, in some cases, photons enter the SPAD 61, to thus cause an avalanche breakdown if the potential of the node S1 does not lower sufficiently, and the SPAD 61 has, between its anode and cathode, a potential difference corresponding to V_{BD} plus a voltage equivalent to the reduction. In the example in FIG. 6, an avalanche breakdown occurs at time t8, during which the node S1 is discharged, and the node S1 changes back to the logic “H” level (V_{EX}). In this way, the sensitivity of an SPAD with its anode-to-cathode potential difference not lowered sufficiently is lower than that of an SPAD with its anode-to-cathode potential difference corresponding to V_{BD} plus V_{EX}, but it is not to say that there is no longer sensitivity; depending on the situation, an avalanche breakdown occurs in reaction to incident photons in some cases.

Further, like the instance in FIG. 5, the node S5 changes to the logic “H” level at time t9, the node S6 changes to the logic “L” level as well at time t10, and the node S7 changes to the logic “H” level at time t11.

However, the node S1 remains at the logic “H” level even at time t12. Thus, unlike that in the instance in FIG. 5, the node S8 remains at the logic “H” level during only the period Δt2, which is determined by the delay circuit 68, and changes to the logic “L” level at time t12. That is, the MOS transistor 63 is turned on during only times t7 to t12 (Δt2), and thereafter, the MOS transistor 63 is turn off temporarily though the node S1 is not discharged sufficiently.

Then, an operation result in the NOR gate 71, that is, the node S9 changes to the logic “H” level at time t13, and the node S4 changes to the logic “L” level at time t14. Further, the node S5 changes to the logic “L” at time t15, which is after a lapse of the period Δt2 measured from time t14. Then, at time t16, the node S6 changes to the logic “H” level, and the node S8 stands at the logic “L” level; thus, the node S9 changes to the logic “L” level at time t17. In consequence of this transition of the node S9 to the logic “L” level, an operation result in the NOR gate 69, that is, the node S4 changes to the “H” level at time t18. Then, the node S7 changes to the “L” level at time t19, and the node S8 changes to the “H” level at time t20. Consequently, the MOS transistor 63 is turned on again, discharging the node S1.

The subsequent operations are the same as those after time t7 in FIG. 5. FIG. 6 illustrates an instance where the node S1 lowers down to the “L” level, that is, 0 volts, in consequence of the discharge, which is started from time t20. It is noted that when, like the case at time t8, an avalanche breakdown occurs in the SPAD 61 during the discharge, and the potential of the node S1 rises consequently, the node S8 stands at the logic “H” level during only the period Δt2 starting from time t20, like that during times t7 to t12, and thereafter, the node S8 stands at the logic “L” level, followed by the logic “H” level again.

As described above, the light detector 60 according to this embodiment includes the following: the SPAD 61 having an anode connected to the first node S1; the MOS transistor 62 having a drain connected to the first node S1, and functioning as a resistor component; the MOS transistor 63 having a drain connected to the first node S1, and functioning as a switch element; and the control circuit 66 configured to control the MOS transistor 63 to discharge the first node S1. Moreover, in response to a rise in the potential of the first node S1 from a first potential (e.g., 0 volts, a logic “L” level) to a second potential V1 (e.g., a logic “H” level), the control circuit 66 turns on the MOS transistor 63 until the second period Δt2 elapses after a lapse of the first period Δt1 measured from the change to the second potential, or until the potential of the first node S1 changes back to the first potential during the second period Δt2. Moreover, the control circuit 66 turns off the MOS transistor 63 upon a lapse of the second period without the potential of the first node S1 changing back to the first potential (e.g., upon occurrence of an avalanche breakdown again in the SPAD 61 during the discharge), and the control circuit 66 turns on the MOS transistor 63 again after a lapse of a third period (times t12 to t20 in FIG. 6) measured from the turning off of the MOS transistor 63. This configuration enables a dead time in the SPAD 61 to be reduced even if an avalanche breakdown occurs in the SPAD 61 during the discharge of the node S1 starting from time t7, as described with reference to FIG. 6.

In the light detector 60 according to this embodiment illustrated in FIG. 3, the MOS transistor 62 is an n-MOS switch having a high resistance value. Upon entrance of light into the SPAD 61 with a high reverse voltage (V_{BD}+V_{EX}) applied thereto, an avalanche multiplication occurs (avalanche operation), passing a current from the SPAD 61 through the MOS transistor 62. Upon the current flow through the MOS transistor 62, the voltage between the source and drain of the MOS transistor 62 drops, lowering the voltage between the anode and cathode of the SPAD 61 to about the voltage V_{BD} (quench operation), thus stopping the avalanche multiplication. In so doing, using the MOS transistor 63 in addition to the MOS transistor 62 can discharge the node S1 rapidly. This can promptly get the SPAD 61 back into a condition where the SPAD 61 with its anode-to-cathode voltage standing at V_{BD}+V_{EX} can handle a received light pulse.

However, for a mere addition of the MOS transistor 63, a current flowing from the cathode of the SPAD 61 flows through both of the MOS transistors 62 and 63 if an avalanche multiplication occurs during the discharge of the node S1 in the two MOS transistors 62 and 63. Moreover, the current flowing through the SPAD 61 and the current flowing through the MOS transistors 62 and 63 are balanced with each other; accordingly, in some cases, electric charges at the node S1 are not discharged promptly, possibly keeping the node S1 at the logic “H” level. This equilibrium is unstable even under such a phenomenon and is hence disturbed after a certain time period, thus completing the discharge, and the SPAD 61 gets back to sensitivity for a received light pulse. However, a prolonged dead time can be produced, during which the SPAD 61 cannot handle a received light pulse.

That is, the potential of the node S1 does not lower in the balanced state (i.e., an avalanche current is equal to a current discharged by the MOS transistors 62 and 63). However, since this equilibrium is unstable, the avalanche current is no longer equal to the current discharged by the MOS transistor 62 and 63 if this state is disturbed to thus change the potential of the node S1; thus, the equilibrium goes to another stable point at which the node S1 stands at 0 volts (i.e., a state where no avalanche current flows, and where a voltage is applied between SPADs).

In this regard, the MOS transistor 63 is pulse-driven in the configuration according to this embodiment. The effective period (“H” level period in this example) of a pulse signal with which the MOS transistor 63 is controlled is determined in accordance with a delay time in the delay circuit 68 and is set at a time period during which the node S1 can be sufficiently discharged with a single pulse, that is, a time period during which the node S1 can stand at the logic “L” level. Moreover, the potential of the node S1 is monitored via the node S2, and at the time point when the potential of the node S1 has lowered sufficiently, the NOR gate 70 disables the pulse (“L” level in this example). This can minimize the discharge period of the node S1 and can shorten the dead time.

Further, in this preferred embodiment, in the event of a failure to sufficiently discharge the node S1 with a single pulse, for instance, in the event of an occurrence of an avalanche multiplication during the discharge, the second pulse is generated. In so doing, a predetermined time period is provided between the first pulse and the second pulse, and during this period, the MOS transistor 62 performs a quench operation without the use of the MOS transistor 63. Accordingly, even when the current flowing through the SPAD 61 and the current flowing through the MOS transistors 62 and 63 are balanced, using only the MOS transistor 62 disturbs this equilibrium, and immediately after the switching, the current resulting from the avalanche breakdown is larger than the current discharged by the MOS transistor 62; hence, the potential of the node S1 rises, and the voltage between the anode and cathode of the SPAD 61 lowers down to V_{BD}, thereby stopping the current resulting from the avalanche breakdown in the SPAD 61. Thereafter, a pulse signal is generated anew, to thus turn on the MOS transistor 63, thus discharging the node S1. This can prevent a prolonged “H” level state and can shorten the dead time even if an avalanche multiplication occurs again during the discharge.

Further, in this preferred embodiment, the delay time Δt1 is set to be larger than an SPAD received-light-pulse width Δtp. This can reduce the possibility of an avalanche multiplication that occurs during the discharge. That is, an avalanche multiplication tends to occur during the received-light-pulse period Δtp as a matter of course. However, as illustrated in FIG. 5 and FIG. 6, setting the delay time Δt1 to be larger than the received-light-pulse period, during which reflected light from the detection target 2 is incident on the SPAD 61, can avoid an overlap between the received-light-pulse period and discharge period, thereby preventing an avalanche multiplication during the discharge. As a matter of course, an avalanche multiplication occurs in some cases due to ambient light or SPAD noise, even during no reception of reflected light from the detection target 2. In such a case, setting a pulse signal, with which the MOS transistor 63 is driven, sequentially at an “H” level, followed by a “L” level, followed by the “H” level, as described above, prevents dead time prolongation.

As seen above, this preferred embodiment enables a node that is discharged by a quench operation in an SPAD to be reduced rapidly to a low potential using a low-resistance switch element that is pulse-driven. Further, upon occurrence of an avalanche multiplication during the discharge, thus raising the node's potential, the switch element is turned off, a quench operation is performed using a high-resistance switch element (resistor component), and the node is thereafter discharged rapidly using the low-resistance switch element. This can shorten the dead time in the SPAD 61 and can enhance the performance of the range finder 1.

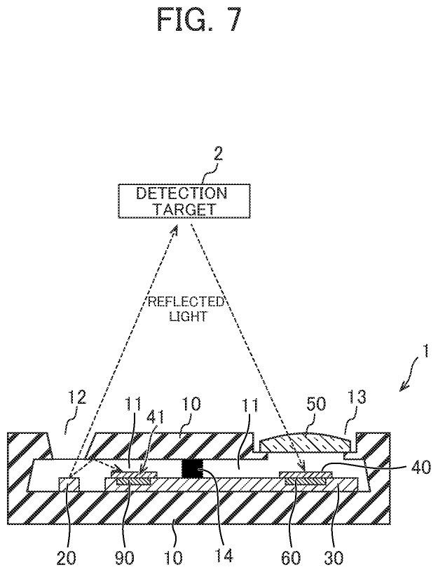

It is noted that the foregoing preferred embodiment is not only one preferred embodiment; various modifications can be devised. For instance, the foregoing has described, with reference to FIG. 1 and FIG. 2, an instance of the range finder 1 where the distance operation circuit 33 measures a distance to the detection target 2 on the basis of a pulse signal from the drive circuit 21, and a pulse signal from the light detector 60. However, a light detector that generates a reference pulse may be provided in some cases. FIG. 7 is a sectional view of the range finder 1 in such a case and corresponds to FIG. 1, described in the foregoing preferred embodiment.

As illustrated, the range finder 1 according to this modification further includes, in the configuration described with reference to FIG. 1, a light detector 90 and an optical filter 41. The light detector 90 is provided within the light-reception IC so as to face the light detector 60 with a light-blocking wall 14 interposed therebetween. The configuration and operation of the light detector 90 are similar to those of the light detector 60 described in the foregoing preferred embodiment. Moreover, the optical filter 41 is disposed on the upper surface of the light detector 90; specifically, the optical filter 41 is disposed so as to cover the light-receiving surfaces of the SPADs of the light detector 90. Moreover, light output from the light-emitting element 20, for instance, reflects on the upper surface in the hollow 11 of the case 10 and then enters the light detector 90.

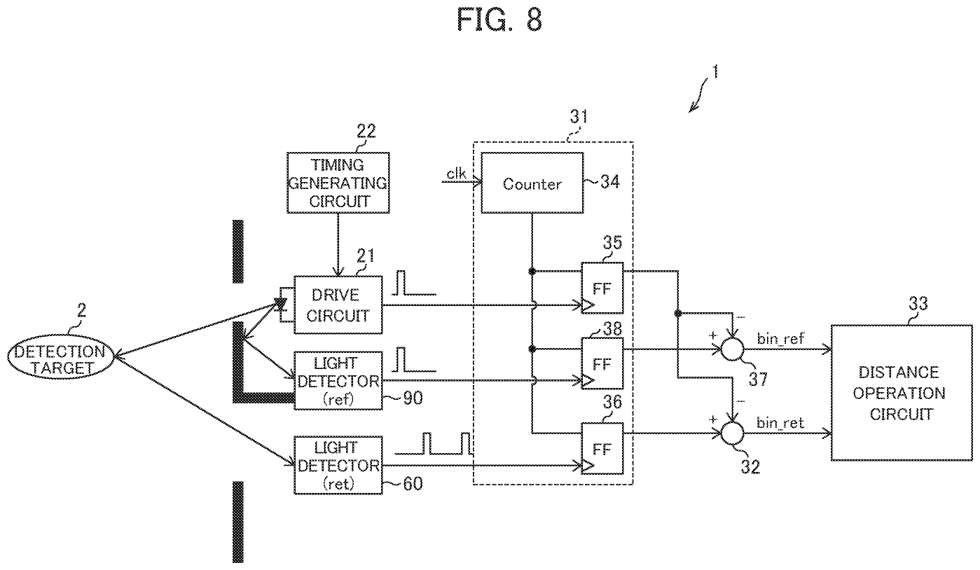

FIG. 8 is a block diagram of the range finder 1 according to this modification and corresponds to FIG. 2, described in the foregoing preferred embodiment. As illustrated, the range finder 1 according to this modification further includes, in the configuration described with reference to FIG. 2, the aforementioned light detector 90, an addition-and-subtraction circuit 37, and a flip-flop 38 provided within the TDC 31.

The light detector 90 outputs a pulse signal to the TDC 31 at a timing synchronized with the timing at which, as earlier described, the SPADs receive reflected light within the case 10. The flip-flop 38 within the TDC 31 is a D-F/F for instance and receives a digital value output by the counter circuit 34, and the pulse signal output by the light detector 90, and the flip-flop 38 retains the digital value at the timing of the reception of the pulse signal and outputs the digital value to the addition-and-subtraction circuit 37. The addition-and-subtraction circuit 37 calculates a difference bin_ref between the digital values output from the flip-flops 35 and 38 and outputs the difference bin_ref to the distance operation circuit 33. Moreover, the distance operation circuit 33 calculates the distance to the detection target 2 on the basis of the difference bin_ret, output by the addition-and-subtraction circuit 32, and the difference bin_ref, output by the addition-and-subtraction circuit 37.

That is, the differences bin_ref and bin_ret are expressed as below.
Difference bin_ref. (a timing of reception of reference light) minus (a timing of VCSEL's light emission)
Difference bin_ret: (a timing of reception of reflected light) minus (a timing of VCSEL's light emission)

Moreover, the distance operation circuit 33 generates individual histograms and calculates a difference in the center of gravity between the histograms as the distance to the detection target 2. A conventionally known method can be used for detailed calculation.

The light received by the light detector 90 is reference light in this configuration. This can reduce delay fluctuations of the light emission in the light-emitting element 20, and the effect of crosstalk light, thereby enabling more accurate distance measurement.

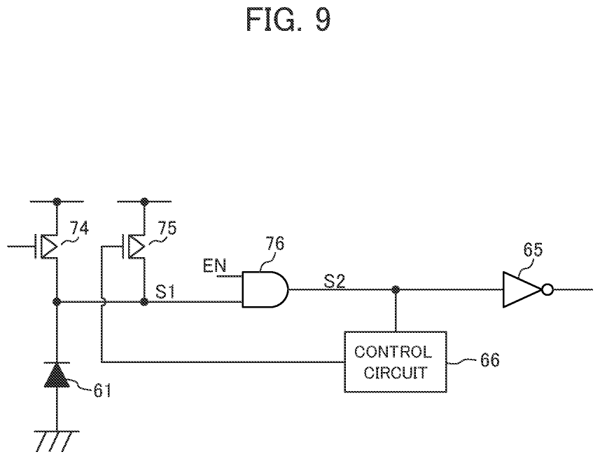

FIG. 9 is a circuit diagram of the light detector 60 according to another modification. The foregoing preferred embodiment has described an instance where, as illustrated in FIG. 3, the cathode of the SPAD 61 is connected to a high-voltage node, and the MOS transistors 62 and 63 are n-channel transistors. However, the configuration in FIG. 3 is non-limiting; a configuration like that in FIG. 9 may be provided.

As illustrated, the light detector 60 according to this modification includes the SPAD 61, the inverter 65, p-channel MOS transistors 74 and 75, an AND gate 76, and the control circuit 66. That is, the light detector 60 according to this modification corresponds to what is illustrated in FIG. 3 with the n-channel MOS transistors 62 and 63 replaced with the p-channel MOS transistors 74 and 75.

The SPAD 61 has a cathode connected to the node S1, and an anode connected to a low-voltage node (e.g., a ground node).

The p-channel MOS transistor 74 has a drain connected to the node S1, a source connected to a high-voltage node, and a gate to which a voltage V_{G} is applied. When the range finder 1 operates, the voltage V_{G} is set at a logic “L” level, thus turning on the MOS transistor 74. As such, the MOS transistor 74 substantially functions as a resistor component. Further, like that in the foregoing preferred embodiment, the potential of the high-voltage node is the sum of a breakdown voltage V_{BD} of the SPAD 61 and an overvoltage V_{EX} of the same. Moreover, the SPAD 61 receives, for instance, reflected light from the detection target 2 during application of the voltage V_{BD} plus V_{EX} between its anode and cathode, to generate an avalanche breakdown, thus passing a current from the cathode to the anode.

The p-channel MOS transistor 75 has a drain connected to the node S1, a source connected to the high-voltage node, and a gate to which the signal S8, supplied from the control circuit 66, is input. Moreover, the MOS transistor 75 is turned on when the node S8 is at the logic “L” level. As such, the MOS transistor 75 substantially functions as a switch element and charges the node S1. It is noted that the resistance value between the source and drain in at least the linear region and saturated region of the MOS transistor 75 is smaller than the resistance value between the source and drain of the MOS transistor 74.

The AND gate 76 performs an AND operation between a signal of the node S1 and a signal EN and outputs the operation result to the node S2. When the range finder 1 operates, the signal EN is set at a logic “H” level. Thus, the AND gate 76 outputs the logic “H” level when the node S1 is at the logic “H” level, and the AND gate 76 outputs the logic “L” level when the node S1 is at the logic “L” level. It is noted that the AND gate 76 may be replaced with a NAND gate and may have a non-limiting configuration that enables the potential of the node S1 to be transmitted to the control circuit 66 via the node S2.

The control circuit 66 controls the MOS transistor 75 in accordance with the logic level of the node S2, to charge the node S1. That is, in response to a drop in the potential of the node S1 from a first potential (in this example, V_{BD}+V_{EX}) to a second potential (in this example, a voltage V1 is equal to a potential corresponding to the logic “L” level), the control circuit 66 turns on the MOS transistor 75 until a second period Δt2 elapses after a lapse of a first period Δt1 measured from the change to the second potential, or until the potential of the node S1 changes back to the first potential during the second period Δt2, the control circuit 66 turns off the MOS transistor 75 upon a lapse of the second period Δt2 without the potential of the node S1 changing back to the first potential, and the control circuit 66 turns on the MOS transistor 75 again after a lapse of a third period measured from the turning off the MOS transistor 75. That is, this control circuit 66 operates in a manner similar to that in the control circuit 66 described in the foregoing preferred embodiment with the exception that the logic relationship between the nodes S1 and S8 (“H” level or “L” level) is reverse.

To be more specific, the control circuit 66 pulse-drives the MOS transistor 75. The effective period (“L” level period in this example) of a pulse signal with which the MOS transistor 75 is controlled is set at a time period during which the node S1 can be sufficiently charged with a single pulse, that is, a time period during which the node S1 can stand at the logic “H” level. Moreover, the potential of the node S1 is monitored via the node S2, and at the time point when the potential of the node S1 has risen sufficiently, the pulse is disabled (“H” level in this example). This can minimize the charge period of the node S1 and can shorten a dead time.

Further, in this preferred embodiment, in the event of a failure to sufficiently charge the node S1 with a single pulse, for instance, in the event of an occurrence of an avalanche multiplication during the charge, the second pulse is generated. In so doing, a predetermined time period is provided between the first pulse and the second pulse, and during this period, the MOS transistor 74 performs a quench operation without the use of the MOS transistor 75. Accordingly, even when the current flowing through the SPAD 61 and the current flowing through the MOS transistors 74 and 75 are balanced, using only the MOS transistor 74 disturbs this equilibrium, and immediately after the switching, the current resulting from the avalanche breakdown is larger than the current charged by the MOS transistor 74; hence, the potential of the node S1 lowers, and the voltage between the anode and cathode of the SPAD 61 lowers down to V_{BD}, thereby stopping the current resulting from the avalanche breakdown in the SPAD 61. Thereafter, a pulse signal is generated anew, to thus turn on the MOS transistor 75, thus charging the node S1. This can prevent an avalanche multiplication from occurring again during the charge and can shorten the dead time.

It is noted that in the configuration illustrated in FIG. 8, the two light detectors 60 and 90 desirably have the same circuit configuration. That is, it is desirable that both of the two light detectors 60 and 90 have the configuration illustrated in FIG. 3, or the configuration illustrated in FIG. 9.

Further, the circuit configurations described in the foregoing preferred embodiment and modifications are mere examples; various modifications can be devised. In particular, the control circuit 66 needs to be configured to be able to control the MOS transistors 63 and 75 appropriately as described above; for instance, the control circuit 66 may control them by software, such as a processor.

Furthermore, the range finder 1 is commonly configured such that a plurality of SPADs 61 are disposed in, for instance, matrix. In such a case, if the number of SPADs 61 is increased that are in the dead time due to ambient light or other things even though there are sufficiently many SPADs 61, the sensitivity of the range finder 1 degrades. Thus, this preferred embodiment is effective particularly in such a use application. Further, for an application that is used under a bright environment, an avalanche multiplication highly probably occurs during the charge and discharge of the node S1; accordingly, this preferred embodiment is effective for such an application. The range finder 1 according to the foregoing preferred embodiment is applicable to, but not limited to, smartphones and autonomous vacuum cleaners. For application to a smartphone for instance, the range finder 1 can measure its distance to a user, and when the user puts the smartphone to the user's ear for conversation for instance, the range finder 1 can detect that the distance to the user has reached a given distance or closer, to thus disable what is displayed or its touch panel function. For application to an autonomous vacuum cleaner, the range finder 1 can be used to detect obstacles, such as walls and pieces of furniture.

While the foregoing has described the preferred embodiment of the present invention, the present invention is not limited to this embodiment; modifications can be made appropriately. The foregoing configurations can be replaced with a substantially similar configuration, a configuration that exerts a substantially similar action and effect, or a configuration that can achieve a substantially similar object.

While there have been described what are at present considered to be certain embodiments of the invention, it will be understood that various modifications may be made thereto, and it is intended that the appended claims cover all such modifications as fall within the true spirit and scope of the invention.

What is claimed is:

1. Alight detector comprising:
a single-photon avalanche diode (SPAD) having one end connected to a first node;
a resistor component having one end connected to the first node;
a switch element having one end connected to the first node; and
a control circuit configured to control the switch element to discharge or charge the first node,
wherein in response to a change in a potential of the first node from a first potential to a second potential,
the control circuit turns on the switch element until a second period elapses after a lapse of a first period measured from the change to the second potential, or until the potential of the first node changes back to the first potential during the second period, and
the control circuit turns off the switch element upon a lapse of the second period without the potential of the first node changing back to the first potential, and the control circuit turns on the switch element again after a lapse of a third period measured from the turning off of the switch element.

2. The light detector according to claim 1, wherein
the control circuit includes
a first delay circuit configured to delay a signal based on the potential of the first node,
a determination circuit configured to determine whether to discharge or charge the first node in accordance with an output of the first delay circuit,
a first pulse control circuit configured to generate, in accordance with an output of the determination circuit, a pulse signal that enables the switch element to be turned on during the second period,
a second pulse control circuit configured to disable the pulse signal in response to a change in the potential of the first node from the second potential to the first potential, and
a third pulse control circuit configured to cause the determination circuit to determine again whether to discharge or charge the first node, upon a lapse of the second period without the potential of the first node reaching the first potential.

3. The light detector according to claim 2, wherein
the first pulse control circuit includes
a second delay circuit configured to delay an output signal of the determination circuit, and
a pulse generating circuit configured to generate the pulse signal enabled during the second period, in accordance with an input signal to the second delay circuit and an output signal of the second delay circuit.

4. The light detector according to claim 3, wherein the second pulse control circuit receives the pulse signal output from the first pulse control circuit and disables the pulse signal in accordance with a signal based on the potential of the first node.

5. The light detector according to claim 4, wherein the third pulse control circuit generates a signal for determining whether to discharge or charge the first node, in accordance with a signal based on the second delay circuit and an output signal of the second pulse control circuit.

6. The light detector according to claim 2, wherein a transition speed of a logic level of an output signal of the first delay circuit is different between a transition of an input signal of the first delay circuit from a first logic level to a second logic level different from the first logic level, and a transition of the input signal from the second logic level to the first logic level.

7. The light detector according to claim 1, wherein
the potential of the first node rises or lowers from the first potential to the second potential in consequence of a voltage drop based on a current that flows in consequence of a breakdown in the SPAD, and
in response to an occurrence of a breakdown in the SPAD again during the second period, the second period elapses without the potential of the first node reaching the first potential.

8. The light detector according to claim 1, wherein
the SPAD has an anode being the one end of the SPAD, and a cathode connected to a high-voltage node,
the resistor component is a first n-channel MOS transistor having a drain being the one end of the resistor component, and a source connected to a low-voltage node,
the switch element is a second n-channel MOS transistor having a drain being the one end of the switch element, a source connected to the low-voltage node, and a gate configured to be controlled by the control circuit, the second n-channel MOS transistor having a smaller on-resistance than the first n-channel MOS transistor,
a resistance value between the source and the drain of the resistor component is larger than a resistance value between the source and the drain of the switch element, and
the control circuit discharges, to the low-voltage node, an electric charge charged at the first node in consequence of a breakdown in the SPAD, by outputting a pulse signal of a logic “High” level to turn on the second n-channel MOS transistor.

9. The light detector according to claim 1, wherein
the SPAD has a cathode being the one end of the SPAD, and an anode connected to a low-voltage node,
the resistor component is a first p-channel MOS transistor having a drain being the one end of the resistor component, and a source connected to a high-voltage node,
the switch element is a second p-channel MOS transistor having a drain being the one end of the switch element, a source connected to the high-voltage node, and a gate configured to be controlled by the control circuit, the second p-channel MOS transistor having a smaller on-resistance than the first p-channel MOS transistor,
a resistance value between the source and the drain of the resistor component is larger than a resistance value between the source and the drain of the switch element, and
the control circuit charges, from the high-voltage node, the first node discharged in consequence of a breakdown in the SPAD, by outputting a pulse signal of a logic “Low” level to turn on the second p-channel MOS transistor.

10. A range finder comprising:
a light-emitting element configured to emit pulsed light to a detection target at predetermined time intervals;
a light detector configured to receive reflected light that is the pulsed light emitted from the light-emitting element, and that is reflected on the detection target; and
a distance operation circuit configured to perform an operation of a distance to the detection target in accordance with a timing at which the pulsed light is emitted by the light-emitting element, and a timing at which the reflected light is received by the light detector,
wherein the light detector includes
a single-photon avalanche diode (SPAD) having one end connected to a first node, and configured to receive the reflected light,
a resistor component having one end connected to the first node,
a switch element having one end connected to the first node, and
a control circuit configured to control the switch element to discharge or charge the first node, and
wherein in response to a change in a potential of the first node from a first potential to a second potential,
the control circuit turns on the switch element until a second period elapses after a lapse of a first period measured from the change to the second potential, or until the potential of the first node changes back to the first potential during the second period, and
the control circuit turns off the switch element upon a lapse of the second period without the potential of the first node changing back to the first potential, and the control circuit turns on the switch element again after a lapse of a third period measured from the turning off of the switch element.
